(19) United States
(12) Patent Application Publication
(10) Pub. No.: US 2024/0068881 A1
(43) Pub. Date: Feb. 29, 2024

(54) THERMOELECTRIC CONVERSION DEVICE

(71) Applicant: Murata Manufacturing Co., Ltd., Nagaokakyo-shi, Kyoto-fu (JP)

(72) Inventors: Eiichi MAEDA, Nagaokakyo-shi (JP); Masashi HATTORI, Nagaokakyo-shi (JP); Mitsuru ODAHARA, Nagaokakyo-shi (JP); Toru TAKAHASHI, Nagaokakyo-shi (JP); Kojiro KOMAGAKI, Nagaokakyo-shi (JP); Takahiro TAGUCHI, Nagaokakyo-shi (JP)

(21) Appl. No.: 18/504,562

(22) Filed: Nov. 8, 2023

Related U.S. Application Data
(63) Continuation of application No. PCT/JP22/25585, filed on Jun. 27, 2022.

(30) Foreign Application Priority Data
Jun. 30, 2021 (JP) 2021-108583

(51) Int. Cl. G01K 7/04

(52) U.S. Cl. CPC G01K 7/04

(57) ABSTRACT

A thermoelectric conversion device that includes an element body including a plurality of stacked; and a meandering wire inside the element body and that has a stacked structure. The meandering wire includes a thermoelectric material that has an anomalous Nernst effect, and a thermal conductivity of the plurality of stacked substrates is lower than that of the thermoelectric material. A thermoelectric conversion device that includes a winding core; and a winding wire wound around the winding core. The winding wire consists only of a thermoelectric material that has an anomalous Nernst effect. A thermoelectric conversion device that includes a plurality of substrates and meandering wires on main surfaces of the respective substrates. The meandering wires include a thermoelectric material that has an anomalous Nernst effect, and the substrates adjacent to each other are arranged at an angle that is larger than 0 degrees and smaller than 180 degrees.

### CROSS REFERENCE TO RELATED APPLICATIONS

The present application is a continuation of International application No. PCT/JP2022/025585, filed Jun. 27, 2022, which claims priority to Japanese Patent Application No. 2021-108583, filed Jun. 30, 2021, the entire contents of each of which are incorporated herein by reference.

### TECHNICAL FIELD

The present invention relates to a thermoelectric conversion device.

### Background Art

As an example of a thermoelectric conversion device that converts heat into electricity with the use of a temperature difference in a material, Patent Document 1 discloses a film-shaped heat flux sensor. The heat flux sensor described in Patent Document 1 includes: a flexible film-shaped insulating member with a first surface and a second surface on the opposite side from the first surface; a plurality of first thermoelectric members disposed inside the insulating member and including a first thermoelectric material; a plurality of second thermoelectric members disposed inside the insulating member, including a second thermoelectric material that is different from the first thermoelectric material, and alternately arranged with each of the plurality of first thermoelectric members; a plurality of first conductor patterns disposed on the first surface side with respect to the plurality of first thermoelectric members and the plurality of second thermoelectric members, and connecting the first thermoelectric member and second thermoelectric member arranged adjacent to each other among the plurality of first thermoelectric members and the plurality of second thermoelectric members; and a plurality of second conductor patterns disposed on the second surface side with respect to the plurality of first thermoelectric members and the plurality of second thermoelectric members, and connecting the first thermoelectric member and second thermoelectric member arranged adjacent to each other among the plurality of first thermoelectric members and the plurality of second thermoelectric members.
Patent Document 1: Japanese Patent No. 6658572

### SUMMARY OF THE INVENTION

The heat flux sensor described in Patent Document 1 is installed on the measurement surface of an object to be measured, with one of the first surface and the second surface in contact with the measurement surface of the object to be measured. A heat flow passes through the heat flux sensor in a direction from one of the first surface and second surface of the heat flux sensor toward the other thereof. In this case, a temperature difference is caused between the first surface side and second surface side of the heat flux sensor. More specifically, a temperature difference is caused between one side and the other side for each of the first thermoelectric member and second thermoelectric member connected to each other. Thus, a thermoelectromotive force is generated across the first thermoelectric member and the second thermoelectric member by the Seebeck effect. The heat flux sensor described in Patent Document 1 outputs this thermoelectromotive force, specifically, the voltage as a sensor signal.

The heat flux sensor described in Patent Document 1 has, however, the problem of being insufficient for applications with small installation areas, because of the low electromotive voltage with respect to the temperature difference per installation area.

The present invention has been made to solve the problem mentioned above, and an object of the present invention is to provide a thermoelectric conversion device capable of achieving a sufficient electromotive voltage per unit installation area also in the case of a small temperature difference.

A thermoelectric conversion device according to the present invention includes, in a first aspect thereof, an element body including a plurality of stacked substrates; and a meandering wire inside the element body and that has a stacked structure. The meandering wire includes a thermoelectric material that an anomalous Nernst effect, and a thermal conductivity of the plurality of stacked substrates is lower than that of the thermoelectric material.

A thermoelectric conversion device according to the present invention, in a second aspect thereof, includes a winding core; and a winding wire wound around the winding core. The winding wire consists only of a thermoelectric material that has an anomalous Nernst effect.

A thermoelectric conversion device according to the present invention, in a third aspect thereof, includes a plurality of substrates; and a plurality of meandering wires on respective main surfaces of each of the plurality of substrates. The plurality of meandering wires include a thermoelectric material that has an anomalous Nernst effect, and adjacent substrates of the plurality of substrates are arranged at an angle that is larger than 0 degrees and smaller than 180 degrees.

The present invention can provide a thermoelectric conversion device capable of achieving a sufficient electromotive voltage per unit installation area also in the case of a small temperature difference.

### BRIEF EXPLANATION OF THE DRAWINGS

FIG. 1 is a perspective view schematically illustrating an example of a thermoelectric conversion device according to a first embodiment of the present invention.

FIG. 2 is an exploded perspective view of the thermoelectric conversion device illustrated in FIG. 1.

FIG. 3 is a sectional view of the thermoelectric conversion device illustrated in FIG. 2 taken along a line III-III.

FIG. 4 is an exploded perspective view schematically illustrating a first modification example of the thermoelectric conversion device according to the first embodiment of the present invention.

FIG. 5 is an exploded perspective view schematically illustrating a second modification example of the thermoelectric conversion device according to the first embodiment of the present invention.

FIG. 6 is an exploded perspective view schematically illustrating a third modification example of the thermoelectric conversion device according to the first embodiment of the present invention.

FIG. 7 is a perspective view schematically illustrating an example of the thermoelectric conversion device according to the first embodiment of the present invention in a chip form.

FIG. 8 is an enlarged perspective view of a part surrounded by a dashed line in FIG. 7.

FIG. 9 is a perspective view schematically illustrating an example of the thermoelectric conversion device illustrated in FIG. 7 provided with no via conductors.

FIG. 10 is a perspective view schematically illustrating another example of the thermoelectric conversion device according to the first embodiment of the present invention in a chip form.

FIG. 11 is a perspective view schematically illustrating an example of the thermoelectric conversion device illustrated in FIG. 7 or 10, divided into individual pieces.

FIG. 12 is an exploded perspective view schematically illustrating a fourth modification example of the thermoelectric conversion device according to the first embodiment of the present invention.

FIG. 13 is an exploded perspective view schematically illustrating a fifth modification example of the thermoelectric conversion device according to the first embodiment of the present invention.

FIG. 14 is an exploded perspective view schematically illustrating a sixth modification example of the thermoelectric conversion device according to the first embodiment of the present invention.

FIG. 15 is a perspective view schematically illustrating an example of a thermoelectric conversion device according to a second embodiment of the present invention.

FIG. 16 is a sectional view of the thermoelectric conversion device illustrated in FIG. 15 taken along a line XVI-XVI.

FIG. 17 is a perspective view schematically illustrating an example of a thermoelectric conversion device according to a third embodiment of the present invention.

FIG. 18 is an exploded perspective view of the thermoelectric conversion device illustrated in FIG. 17.

### DETAILED DESCRIPTION OF THE INVENTION

Hereinafter, the thermoelectric conversion device according to the present invention will be described.

However, the present invention is not to be considered limited to the following configurations, and can be appropriately modified and then applied without changing the scope of the present invention. It is to be noted that the present invention also includes a combination of two or more of individual desirable configurations described below.

In the thermoelectric conversion devices according to the present invention, the total extension of wires or the winding wire containing a thermoelectric material can be increased in length. Thus, the electromotive voltage generated by a temperature gradient can be increased.

The thermoelectric conversion device according to the present invention is, for example, a chip component. When the thermoelectric conversion device has a chip structure, the thermoelectric conversion device can be mounted on an electronic substrate by soldering or the like.

Obviously, each of the following embodiments is considered by way of example, and some of the configurations illustrated in the different embodiments can be replaced or combined. In the second and subsequent embodiments, the description of matters that are common to the first embodiment will be omitted, and only the differences will be described. In particular, the same actions and effects achieved by the same configurations will not be sequentially described for each embodiment.

The following drawings are schematic views, and the dimensions, the scales of aspect ratios, and the like may be different from those of actual products.

### First Embodiment

A thermoelectric conversion device according to a first embodiment of the present invention includes an element body including a plurality of substrates that are stacked, and a meandering wire that is provided inside the element body and has a stacked structure. The meandering wire includes a thermoelectric material that has an anomalous Nernst effect.

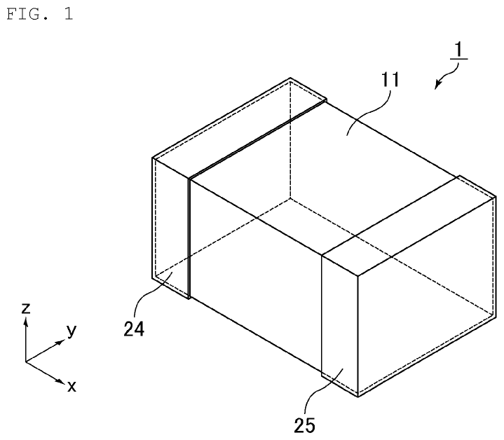

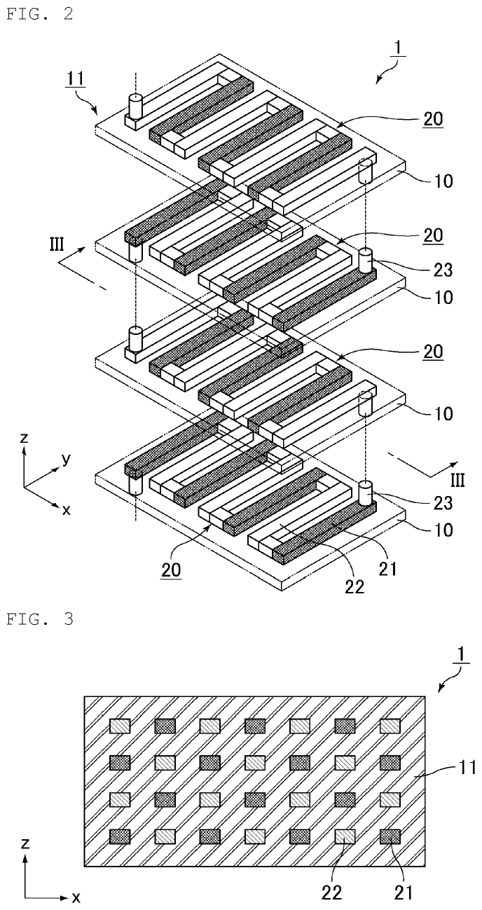

FIG. 1 is a perspective view schematically illustrating an example of the thermoelectric conversion device according to the first embodiment of the present invention. FIG. 2 is an exploded perspective view of the thermoelectric conversion device illustrated in FIG. 1. FIG. 3 is a sectional view of the thermoelectric conversion device illustrated in FIG. 2 taken along a line III-III. In FIGS. 2 and 3, external electrodes are omitted.

The thermoelectric conversion device 1 illustrated in FIG. 1 is a chip component. As illustrated in FIGS. 2 and 3, the thermoelectric conversion device 1 includes an element body 11 including a plurality of stacked substrates 10, and a meandering wire 20 that is provided inside the element body 11 and has a stacked structure. As illustrated in FIG. 1, the outline of the thermoelectric conversion device 1 is, for example, a polygonal prism such as a rectangular parallelepiped.

In the example illustrated in FIGS. 2 and 3, the plurality of substrates 10 are stacked in the z-axis direction to constitute the element body 11. The element body 11 may include the substrate 10 without the meandering wire 20 provided. The number of substrates 10 provided with meandering wire 20 is not particularly limited, but is, for example, 2 or more and 100 or less.

In the present specification, the meandering wire means a wiring extending in one direction while meandering. The shape of the meandering wire may have an angular corner or a chamfered corner.

In the example illustrated in FIG. 2, the meandering wire 20 is provided on the main surface of each substrate 10, and extending in the x-axis direction while meandering. As illustrated in FIG. 2, the meandering wire 20 is preferably provided on the main surface facing in the positive direction, of the main surfaces facing each other in the z-axis direction for each substrate 10. The meandering wire 20 in planar view may have the same shape on the respective substrates 10, or differ in shape between the substrates 10.

The meandering wire 20 includes a thermoelectric material that has an anomalous Nernst effect. The anomalous Nernst effect is a phenomenon in which a voltage is generated in a direction (outer product direction) orthogonal to each of a magnetization direction of a magnetized magnetic body and a heat flow direction, when the heat flow is applied to flow in the magnetic body.

For controlling the magnetization direction to increase the electromotive voltage, a first wire 21 including a thermoelectric material and a second wire 22 including a conductor are preferably alternately arranged for the meandering wire 20 on the main surface of each substrate 10 as illustrated in FIG. 2. It is to be noted that the meandering wire 20 may include only the first wire 21 including a thermoelectric material.

Examples of the thermoelectric material constituting the first wire 21 include Fe₃Sn, Fe₃Al, Fe₃Ga, Fe₃Ge, Co₂MnGa, Co₂MnAl, Co₂MnIn, Mn₃Ga, Mn₃Sn, Mn₃Ge, Fe₂NiGa, CoTiSb, CoVSb, CoCrSb, CoMnSb, and TiGa₂Mn.

Examples of the conductor constituting the second wire 22 include Ag, Cu, Au, Ni, and Pt.

In the example illustrated in FIG. 2, the meandering wire 20 has a stacked structure in the z-axis direction, and is connected between the substrates 10 adjacent to each other in the stacking direction (z-axis direction in FIG. 2). Specifically, the meandering wires 20 between the respective substrates 10 are electrically connected with via conductors 23 interposed therebetween. Accordingly, the meandering wire 20 extends in the main surface direction of the substrate 10 and has a stacked structure in the stacking direction of the substrate 10.

The meandering wire 20 containing the thermoelectric material that has an anomalous Nernst effect is connected between the substrates 10, thereby allowing the total extension of the wires containing the thermoelectric material to be increased in length. Thus, a sufficient electromotive voltage per unit installation area can be obtained also in the case of a small temperature difference.

For example, in FIG. 2, in a case where all of the first wires 21 including a thermoelectric material are magnetized in the positive direction of the x axis, a temperature difference is caused in the negative direction of the z axis when a heat flow flows in the negative direction of the z axis. Thus, the first wires 21 including a thermoelectric material have a voltage generated by the anomalous Nernst effect in an outer product direction (that is, the positive direction of the y axis) orthogonal to each of the magnetization direction (the positive direction of the x axis) and the heat flow direction (the negative direction of the z axis).

In addition, the meandering wire 20 is made to have a stacked structure in a chip shape, thereby increasing heat dissipation from the side wall, and increasing the temperature difference, and as a result, the lower layer increases the electromotive voltage at thermal equilibrium.

As illustrated in FIG. 1, external electrodes 24 and 25 electrically connected to the meandering wires 20 are preferably provided on the surface of the element body 11.

The material constituting the substrate 10 is not particularly limited, but is preferably a ceramic material that is low in thermal conductivity and low in electrical conductivity. Examples of the ceramic material constituting the substrate 10 include an aluminum nitride, a boron nitride, a silicon carbide, alumina, a spinel-type oxide, and a perovskite-type oxide. The material constituting the substrate 10 may be a ceramic material, a glass material, or a resin material. In a case where the thermoelectric material and the substrate 10 are subjected to co-firing, the material is preferably a low-temperature co-fired ceramic material for keeping the ordered phase of the thermoelectric material from being changed. Examples of the low-temperature co-fired ceramic material include a composite material containing borosilicate glass and alumina. From the viewpoint of causing a larger heat flow to flow through the meandering wire 20 to generate a higher electromotive voltage, the ceramic material constituting the substrate 10 is preferably lower in thermal conductivity. In the case of measuring an instantaneous change in heat flux, however, the ceramic material constituting the substrate 10 is preferably higher in thermal conductivity from the viewpoint of causing the heat flow to flow quickly to the thermoelectric conversion device 1. From the viewpoint of suppressing an electrical short circuit between the meandering wires 20, the ceramic material constituting the substrate 10 is preferably lower in electrical conductivity.

The material constituting the substrate 10 may contain a material that has a temperature coefficient of resistance. For example, when the substrate 10 contains a material that has a negative temperature coefficient of resistance (Negative Temperature Coefficient, NTC), the ambient temperature and the heat flux can be simultaneously measured by forming an internal conductor for temperature detection inside the chip component.

For the thermoelectric conversion device according to the first embodiment of the present invention, a magnet is preferably disposed on one end surface of the chip component from the viewpoint of increasing the electromotive voltage. In that case, on an end surface facing the end surface with the magnet disposed thereon, another magnet oriented to the same magnetic pole is more preferably disposed. For example, for the thermoelectric conversion device 1 illustrated in FIGS. 1 to 3, a magnet is preferably disposed on one of the end surfaces facing each other in the x-axis direction, and another magnet oriented to the same magnetic pole is more preferably disposed on the other end surface.

In a case where a magnet is disposed on the end surface of the chip component, the magnetic field direction formed by the magnet is preferably a direction perpendicular to the direction in which the current flows through the first wire and the heat flow direction. For example, in the thermoelectric conversion device 1 illustrated in FIGS. 1 to 3, a magnetic field is preferably formed in the x-axis direction.

For the thermoelectric conversion device according to the first embodiment of the present invention, a high thermal conductive member (also referred to simply as a thermal conductive member) such as a heat dissipation sheet is preferably disposed on at least one end surface of the chip component from the viewpoint of increasing the temperature gradient, and thus increasing the electromotive voltage. For example, for the thermoelectric conversion device 1 illustrated in FIGS. 1 to 3, a high thermal conductive member is preferably disposed on an end surface (top surface) facing in the positive direction, of end surfaces facing each other in the z-axis direction, from the viewpoint of promoting heat dissipation from the thermoelectric conversion device 1 to the outside to increase the temperature gradient, and thus increase the thermoelectromotive voltage. In contrast, from the viewpoint of promoting the heat flow from the heat source to the thermoelectric conversion device 1, a high thermal conductive member is preferably disposed on the end surface (bottom surface) facing in the negative direction, of the end surfaces facing each other in the z-axis direction.

For the thermoelectric conversion device according to the first embodiment of the present invention, at least one end surface of the chip component preferably has irregularities from the viewpoint of enhancing the heat dissipation performance to increase the electromotive voltage. For example, for the thermoelectric conversion device 1 illustrated in FIGS. 1 to 3, the end surface (top surface) facing in the positive direction, of the end surfaces facing each other in the z-axis direction, preferably has irregularities.

The thermoelectric conversion device according to the first embodiment of the present invention may include a plurality of meandering wires extending in different orientations between substrates adjacent to each other in the stacking direction. In that case, an electromotive voltage can be obtained from heat fluxes in a plurality of directions.

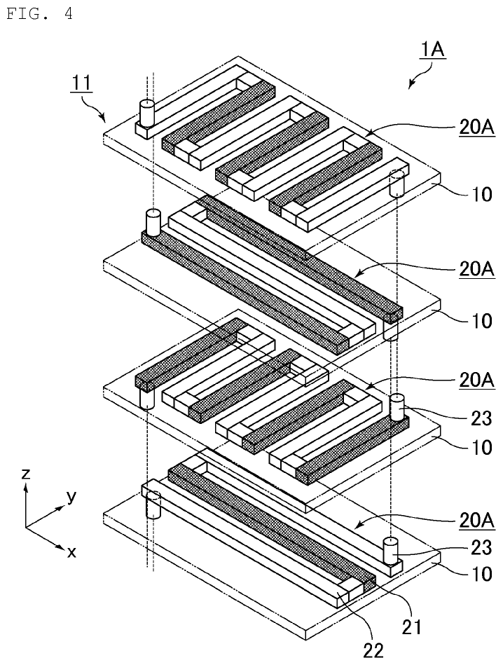

FIG. 4 is an exploded perspective view schematically illustrating a first modification example of the thermoelectric conversion device according to the first embodiment of the present invention.

In the thermoelectric conversion device 1A illustrated in FIG. 4, a meandering wire 20A includes a wire extending in the x-axis direction while meandering and a wire extending in the y-axis direction while meandering.

For example, in FIG. 4, in a case where all of the first wires 21 including a thermoelectric material are magnetized in the negative direction of the z axis, an electromotive voltage can be obtained from heat fluxes in the two directions of the x axis direction and the y axis direction.

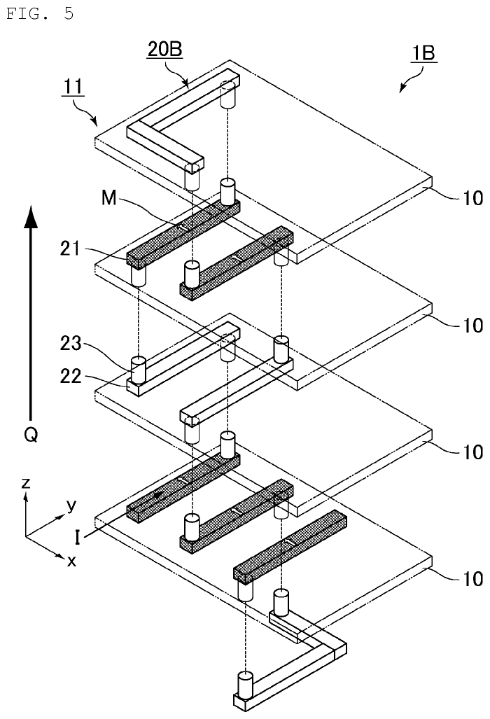

FIG. 5 is an exploded perspective view schematically illustrating a second modification example of the thermoelectric conversion device according to the first embodiment of the present invention.

For the thermoelectric conversion device 1B illustrated in FIG. 5, a plurality of substrates 10 are stacked in the z-axis direction to constitute an element body 11 as with the thermoelectric conversion device 1 illustrated in FIG. 2. In contrast, unlike the thermoelectric conversion device 1 illustrated in FIG. 2, meandering wires 20B extend in the z-axis direction while meandering.

In the example illustrated in FIG. 5, the substrate 10 where a first wire 21 including a thermoelectric material is provided on the main surface and the substrate 10 where a second wire 22 including a conductor is provided on the main surface are alternately stacked in the stacking direction (z-axis direction in FIG. 5) of the substrate 10 to constitute the meandering wires 20B. Between the substrates 10 adjacent to each other in the z-axis direction, the meandering wires 20B are electrically connected with via conductors 23 interposed therebetween.

Furthermore, the meandering wire 20B has a stacked structure in the x-axis direction. The meandering wires 20B adjacent to each other in the x-axis direction are electrically connected with the second wire 22 interposed therebetween. Accordingly, the meandering wire 20B extends in the stacking direction of the substrate 10 and has a stacked structure in the main surface direction of the substrate 10.

For example, in FIG. 5, a current flows in a direction indicated by I, when the first wire 21 including a thermoelectric material has a magnetization direction denoted by M, and a heat flow has a direction denoted by Q.

In the thermoelectric conversion device 1B illustrated in FIG. 5, the first wire 21 and the second wire 22 are provided separately on the main surfaces of the separate substrates 10, unlike the thermoelectric conversion device 1 illustrated in FIG. 2. Thus, the second wire 22 is thinned, thereby allowing the total thickness of the chip component to be reduced without decreasing the sensitivity. For example, the use of, as the conductor that forms the second wire 22, a material that is lower in specific resistance than the thermoelectric material that forms the first wire 21 allows the second wire 22 to be formed to be thinner.

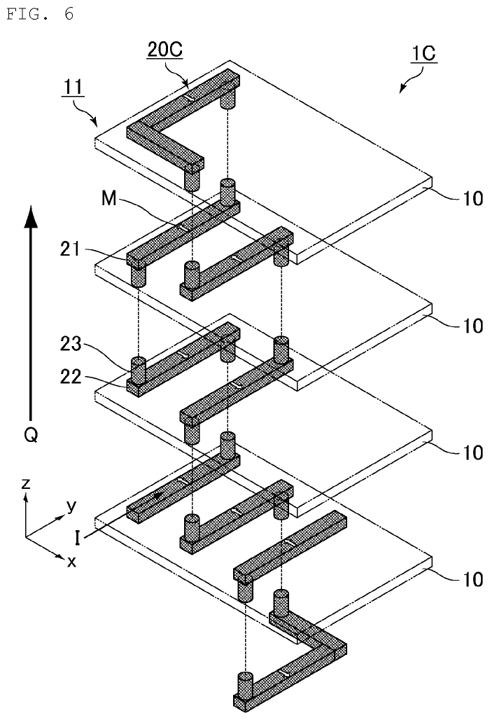

FIG. 6 is an exploded perspective view schematically illustrating a third modification example of the thermoelectric conversion device according to the first embodiment of the present invention.

The thermoelectric conversion device 1C illustrated in FIG. 6 has a configuration that is common to the thermoelectric conversion device 1B illustrated in FIG. 5, except that a meandering wire 20C includes only a first wire 21 including a thermoelectric material. Controlling the magnetization direction of the first wire 21 in accordance with the direction in which a current flows as in FIG. 6 allows the thermoelectric material to be increased in length, thus allowing the electromotive voltage to be increased.

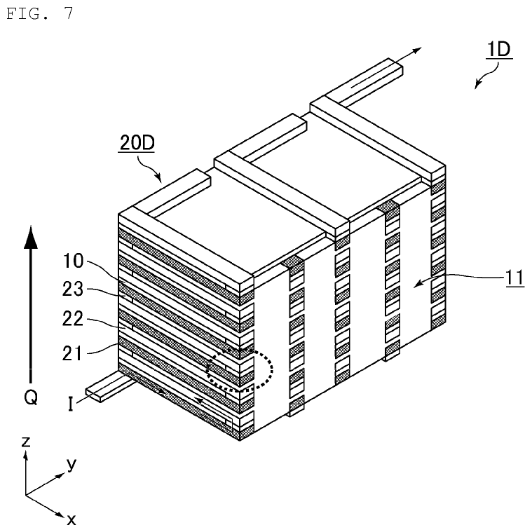

FIG. 7 is a perspective view schematically illustrating an example of the thermoelectric conversion device according to the first embodiment of the present invention in a chip form. FIG. 8 is an enlarged perspective view of a part surrounded by a dashed line in FIG. 7.

For the thermoelectric conversion device 1D illustrated in FIG. 7, the thermoelectric conversion device 1B illustrated in FIG. 5 is drawn in a chip-like form. As illustrated in FIGS. 7 and 8, between the substrates 10 adjacent to each other along the z axis direction, meandering wires 20D are electrically connected with the via conductors 23 interposed therebetween.

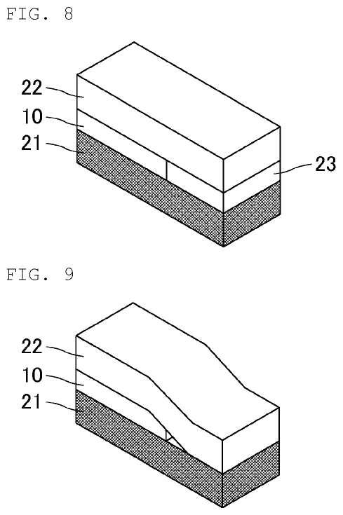

FIG. 9 is a perspective view schematically illustrating an example of the thermoelectric conversion device illustrated in FIG. 7 provided with no via conductors.

As illustrated in FIG. 9, the first wire 21 and the second wire 22 adjacent to each other in the z-axis direction may be directly connected with no via conductor 23 interposed therebetween. Such a structure can be fabricated, for example, by pressing.

In the thermoelectric conversion device 1D illustrated in FIG. 7, the meandering wires 20D may include only the first wire 21 including a thermoelectric material, as with the thermoelectric conversion device 1C illustrated in FIG. 6.

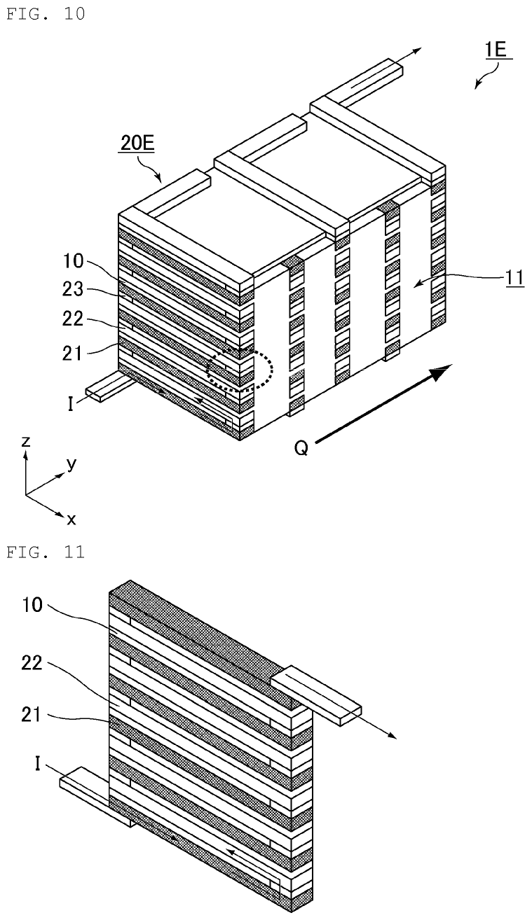

FIG. 10 is a perspective view schematically illustrating another example of the thermoelectric conversion device according to the first embodiment of the present invention in a chip form.

While a heat flow is applied to flow in the z-axis direction in the thermoelectric conversion device 1D illustrated in FIG. 7, a heat flow may be applied to flow in the y-axis direction as in the thermoelectric conversion device 1E illustrated in FIG. 10. For the thermoelectric conversion device 1E illustrated in FIG. 10, the direction Q of the heat flow can be changed from the z-axis direction to the y-axis direction by appropriately changing the magnetization direction M of the first wire 21 included in the meandering wire 20E.

FIG. 11 is a perspective view schematically illustrating an example of the thermoelectric conversion device illustrated in FIG. 7 or 10, divided into individual pieces.

As illustrated in FIG. 11, the thermoelectric conversion device 1D illustrated in FIG. 7 or the thermoelectric conversion device 1E illustrated in FIG. 10 may be cut with a dicer or the like into individual pieces.

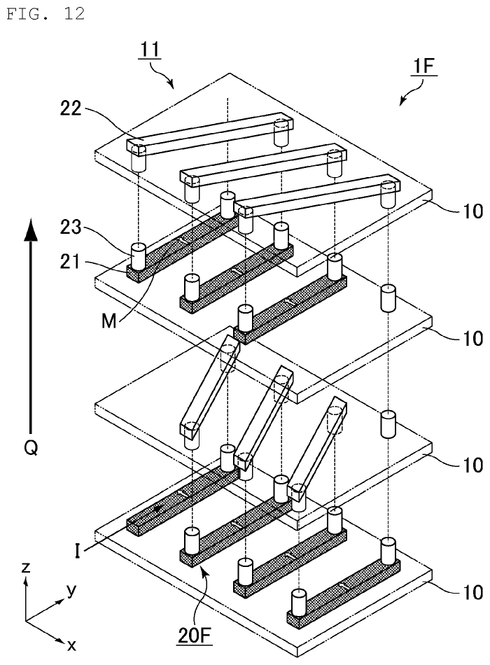

FIG. 12 is an exploded perspective view schematically illustrating a fourth modification example of the thermoelectric conversion device according to the first embodiment of the present invention.

For the thermoelectric conversion device 1F illustrated in FIG. 12, a plurality of substrates 10 are stacked in the z-axis direction to constitute an element body 11 as with the thermoelectric conversion device 1 illustrated in FIG. 2. In contrast, unlike the thermoelectric conversion device 1 illustrated in FIG. 2, meandering wires 20F extend in the x-axis direction while meandering between substrates 10 adjacent in the stacking direction (z-axis direction in FIG. 12).

In the example illustrated in FIG. 12, the substrate 10 where a first wire 21 including a thermoelectric material is provided on the main surface and the substrate 10 where a second wire 22 including a conductor is provided on the main surface are alternately stacked in the stacking direction (z-axis direction in FIG. 12) of the substrate 10 to constitute the meandering wires 20F. Between the substrates 10 adjacent to each other in the z-axis direction, the meandering wires 20F are electrically connected with via conductors 23 interposed therebetween.

Furthermore, the meandering wire 20F has a stacked structure in the z-axis direction. Between the substrates 10 adjacent to each other in the z-axis direction, the meandering wires 20F are electrically connected with via conductors 23 interposed therebetween. Accordingly, the meandering wire 20F extends in the main surface direction of the substrate 10 and has a stacked structure in the stacking direction of the substrate 10.

For example, in FIG. 12, a current flows in a direction indicated by I, when the first wire 21 including a thermoelectric material has a magnetization direction denoted by M, and a heat flow has a direction denoted by Q.

In the thermoelectric conversion device 1F illustrated in FIG. 12, the first wire 21 and the second wire 22 are provided separately on the main surfaces of the separate substrates 10, as with the thermoelectric conversion device 1B illustrated in FIG. 5. Thus, the second wire 22 is thinned, thereby allowing the total thickness of the chip component to be reduced without decreasing the sensitivity. In addition, for the thermoelectric conversion device 1F illustrated in FIG. 12, the second wire 22 provided for the lowermost layer in the thermoelectric conversion device 1B illustrated in FIG. 5 is not required, thereby the total thickness of the chip component to be further reduced.

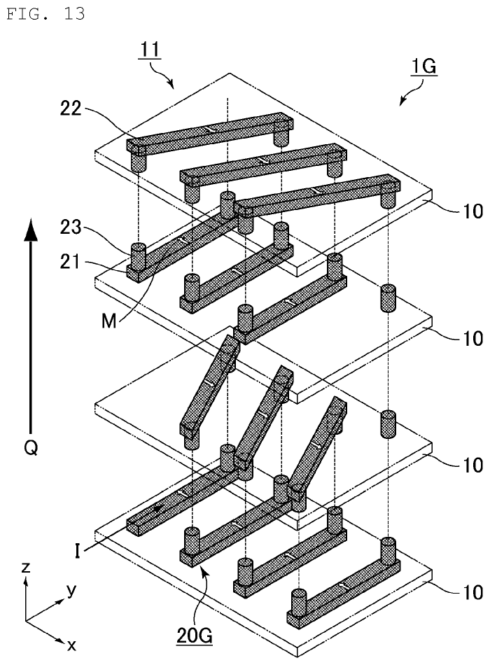

FIG. 13 is an exploded perspective view schematically illustrating a fifth modification example of the thermoelectric conversion device according to the first embodiment of the present invention.

The thermoelectric conversion device 1G illustrated in FIG. 13 has a configuration that is common to the thermoelectric conversion device 1F illustrated in FIG. 12, except that a meandering wire 20G includes only a first wire 21 including a thermoelectric material.

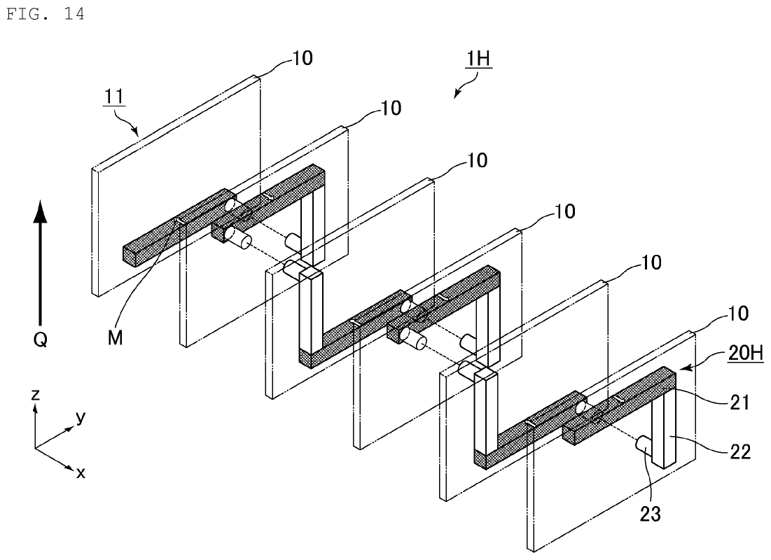

FIG. 14 is an exploded perspective view schematically illustrating a sixth modification example of the thermoelectric conversion device according to the first embodiment of the present invention.

For the thermoelectric conversion device 1H illustrated in FIG. 14, a plurality of substrates 10 are stacked in the x-axis direction to constitute an element body 11. A meandering wire 20H has a stacked structure along the x axis direction. Specifically, the meandering wire 20H is formed in a coil shape. The coil axis of the meandering wire 20H extends along the x axis direction.

As illustrated in FIG. 14, the first wire 21 including a thermoelectric material and second wire 22 including a conductor are preferably alternately arranged for the meandering wire 20H. It is to be noted that the meandering wire 20H may include only the first wire 21 including a thermoelectric material.

The thermoelectric conversion device 1H illustrated in FIG. 14 can be fabricated by using a process for manufacturing a conventional stacked inductor component.

As described above, in the thermoelectric conversion device according to the first embodiment of the present invention, the meandering wire 20 and the like may include the first wire 21 including a thermoelectric material and the second wire 22 including a conductor, or may include only the first wire 21 including a thermoelectric material.

In the thermoelectric conversion device according to the first embodiment of the present invention, the width of the first wire 21 included in the meandering wire 20 and the like is preferably 50 nm or more, more preferably 1 μm or more, still more preferably 20 μm or more from the viewpoint such as reducing the wiring resistance and preventing a disconnection or a short circuit. In contrast, from the viewpoint of increasing the wiring density to increase the total wiring length, the width of the first wire 21 is preferably 5 mm or less, more preferably 500 μm or less, still more preferably 200 μm or less.

In the thermoelectric conversion device according to the first embodiment of the present invention, the thickness of the first wire 21 included in the meandering wire 20 and the like is preferably 50 nm or more, more preferably 1 μm or more, still more preferably 20 μm or more from the viewpoint such as reducing the wiring resistance. Also from the viewpoint of promoting heat dissipation from the side wall to increase the temperature difference, the first wire 21 is preferably thicker. In contrast, when the first wire 21 becomes excessively thick, it becomes difficult to increase the wiring density. Accordingly, the thickness of the first wire 21 is preferably 5 mm or less, more preferably 500 μm or less, still more preferably 200 μm or less.

In the thermoelectric conversion device according to the first embodiment of the present invention, the aspect ratio represented by the thickness of the first wire 21/the width of the first wire 21 is preferably 3 or less. When the aspect ratio is larger than 3, the wire formation becomes difficult. In contrast, the lower limit of the aspect ratio represented by the thickness of the first wire 21/the width of the first wire 21 is not particularly limited, but the aspect ratio is, for example, 0.2 or more.

In the thermoelectric conversion device according to the first embodiment of the present invention, when the meandering wire 20 and the like include the second wire 22, the width of the second wire 22 may be the same as the width of the first wire 21, may be smaller than the width of the first wire 21 from the viewpoint of causing a larger heat flow to flow through the first wire 21 to generate a high electromotive voltage, and may be larger than the width of the first wire 21 from the viewpoint of reducing the electric resistance. In addition, the thickness of the second wire 22 may be the same as the thickness of the first wire 21, may be smaller than the thickness of the first wire 21 from the viewpoint of causing a larger heat flow to flow through the first wire 21 to generate a high electromotive voltage, and may be larger than the thickness of the first wire 21 from the viewpoint of reducing the electric resistance. Furthermore, the aspect ratio represented by the thickness of the second wire 22/the width of the second wire 22 may be the same as the aspect ratio of the first wire 21, may be smaller than the aspect ratio of the first wire 21, or may be larger than the aspect ratio of the first wire 21.

### Second Embodiment

A thermoelectric conversion device according to a second embodiment of the present invention includes a winding core, and a winding wire wound around the winding core. The winding wire includes a thermoelectric material that has an anomalous Nernst effect.

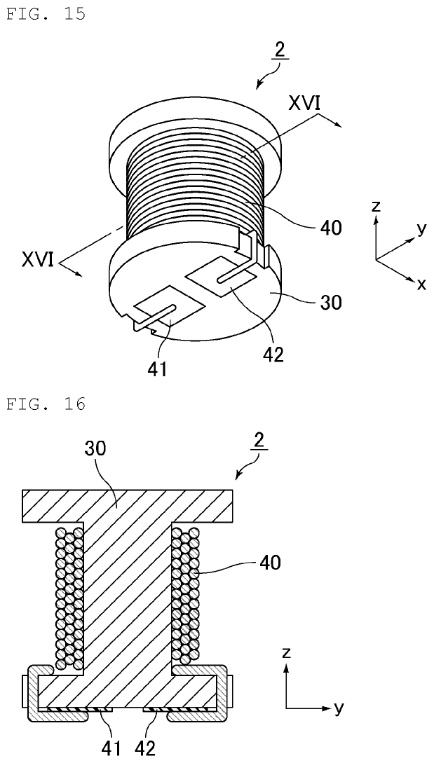

FIG. 15 is a perspective view schematically illustrating an example of a thermoelectric conversion device according to the second embodiment of the present invention. FIG. 16 is a sectional view of the thermoelectric conversion device illustrated in FIG. 15 taken along a line XVI-XVI.

The thermoelectric conversion device 2 illustrated in FIG. 15 is a chip component. As illustrated in FIGS. 15 and 16, the thermoelectric conversion device 2 includes a winding core 30 and a winding wire 40 wound around the winding core 30. As illustrated in FIGS. 15 and 16, the winding core 30 has the shape of, for example, a drum. The shape of the winding core 30 may be a shape with a protrusion at the central part. The winding wire 40 may have a wire shape or a sheet shape.

The winding wire 40 includes a thermoelectric material that has an anomalous Nernst effect. The winding wire 40 may include only a wire or a sheet including a thermoelectric material. The surface of the winding wire 40 is preferably covered with an insulating material. The number of turns of the winding wire 40 is not particularly limited.

The winding wire 40 containing the thermoelectric material that has an anomalous Nernst effect is wound around the winding core 30, thereby allowing the total extension of the wire containing the thermoelectric material to be increased in length. Thus, a sufficient electromotive voltage per unit installation area can be obtained also in the case of a small temperature difference.

For example, in FIGS. 15 and 16, in a case where the winding wire 40 is magnetized in the negative direction of the z axis, when a heat flow flows in a direction perpendicular to the z axis to cause a temperature difference in a direction from the inside of the winding core 30 to the outside thereof, a voltage is generated in an outer product direction orthogonal to each of the magnetization direction and the heat flow direction.

Examples of the thermoelectric material constituting the winding wire 40 include Fe₃Sn, Fe₃Al, Fe₃Ga, Fe₃Ge, Co₂MnGa, Co₂MnAl, Co₂MnIn, Mn₃Ga, Mn₃Sn, Mn₃Ge, Fe₂NiGa, CoTiSb, CoVSb, CoCrSb, CoMnSb, and TiGa₂Mn.

Examples of the insulating material covering the surface of the winding wire 40 include an insulating resin such as a polyimide.

One end of the winding wire 40 is connected to an electrode 41, and the other end is connected to an electrode 42.

The material constituting the winding core 30 is not particularly limited, but is preferably a ceramic material that is high in thermal conductivity and low in electrical conductivity. Examples of the ceramic material constituting the winding core 30 include an aluminum nitride, a boron nitride, a silicon carbide, alumina, a spinel-type oxide, and a perovskite-type oxide. The material constituting the winding core 30 may be a ceramic material, a glass material, or a resin material. In a case where the thermoelectric material and the substrate 10 are subjected to co-firing, the material is preferably a low-temperature co-fired ceramic material for keeping the ordered phase of the thermoelectric material from being changed. Examples of the low-temperature co-fired ceramic material include a composite material containing borosilicate glass and alumina.

The material constituting the winding core 30 may include a material that has a temperature coefficient of resistance. For example, when the winding core 30 contains an NTC material, the ambient temperature and the heat flux can be simultaneously measured by forming an internal conductor for temperature detection inside the chip component.

For the thermoelectric conversion device according to the second embodiment of the present invention, a magnet is preferably disposed on one end surface of the chip component from the viewpoint of increasing the electromotive voltage. In that case, on an end surface facing the end surface with the magnet disposed thereon, another magnet oriented to the same magnetic pole is more preferably disposed. For example, for the thermoelectric conversion device 2 illustrated in FIGS. 15 and 16, a magnet is preferably disposed on one of the end surfaces facing each other in the z-axis direction, and another magnet oriented to the same magnetic pole is more preferably disposed on the other end surface.

In a case where a magnet is disposed on the end surface of the chip component, the magnetic field direction formed by the magnet is preferably a direction perpendicular parallel to the axis of the winding wire. For example, in the thermoelectric conversion device 2 illustrated in FIGS. 15 and 16, a magnetic field is preferably formed in the z-axis direction.

For the thermoelectric conversion device according to the second embodiment of the present invention, a high thermal conductive member such as a heat dissipation sheet is preferably disposed on one end surface of the chip component from the viewpoint of increasing the temperature gradient, and thus increasing the electromotive voltage. For example, for the thermoelectric conversion device 2 illustrated in FIGS. 15 and 16, a high thermal conductive member such as a heat dissipation sheet is preferably disposed on the outer periphery of the winding wire 40.

For the thermoelectric conversion device according to the second embodiment of the present invention, one end surface of the chip component preferably has irregularities from the viewpoint of enhancing the heat dissipation performance to increase the electromotive voltage. For example, for the thermoelectric conversion device 2 illustrated in FIGS. 15 and 16, the surface of the winding core 30 preferably has irregularities.

### Third Embodiment

A thermoelectric conversion device according to a third embodiment of the present invention includes a plurality of substrates and a meandering wire provided on a main surface of each of the substrates. The meandering wire includes a thermoelectric material that an anomalous Nernst effect. The substrates adjacent to each other are arranged at an angle that is larger than 0 degrees and smaller than 180 degrees.

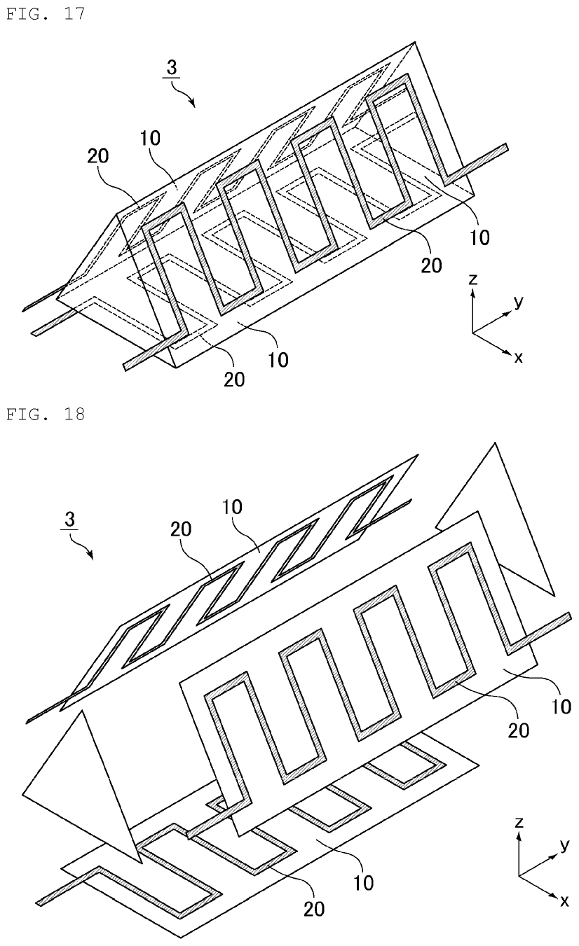

FIG. 17 is a perspective view schematically illustrating an example of a thermoelectric conversion device according to the third embodiment of the present invention. FIG. 18 is an exploded perspective view of the thermoelectric conversion device illustrated in FIG. 17.

The thermoelectric conversion device 3 illustrated in FIG. 17 is a chip component. The thermoelectric conversion device 3 illustrated in FIGS. 17 and 18 includes a plurality of substrates 10 and meandering wires 20 provided on main surfaces of the respective substrates 10. As illustrated in FIG. 17, the outline of the thermoelectric conversion device 3 is, for example, a polygonal prism such as a triangular prism.

As illustrated in FIGS. 17 and 18, the substrates 10 adjacent to each other are arranged at an angle that is larger than 0 degrees and smaller than 180 degrees. The number of substrates 10 provided with meandering wires 20 is not particularly limited, but is, for example, 2 or more and 4 or less.

In the example illustrated in FIGS. 17 and 18, the meandering wires 20 extend in the y-axis direction while meandering. The meandering wire 20 may be provided on the outer main surface or inner main surface of the thermoelectric conversion device 3 of the main surface of each of the substrates 10. The meandering wire 20 in planar view may have the same shape on the respective substrates 10, or differ in shape between the substrates 10.

The meandering wire 20 includes a thermoelectric material that has an anomalous Nernst effect. As described in the first embodiment of the present invention, for controlling the magnetization direction to increase the electromotive voltage, a first wire including a thermoelectric material and a second wire including a conductor may be alternately arranged for the meandering wire 20. It is to be noted that the meandering wires 20 may include only the first wire including a thermoelectric material.

Examples of the thermoelectric material constituting the first wire include Fe₃Sn, Fe₃Al, Fe₃Ga, Fe₃Ge, Co₂MnGa, Co₂MnAl, Co₂MnIn, Mn₃Ga, Mn₃Sn, Mn₃Ge, Fe₂NiGa, CoTiSb, CoVSb, CoCrSb, CoMnSb, and TiGa₂Mn.

Examples of the conductor constituting the second wire include Ag, Cu, Au, Ni, and Pt.

The arrangement of the plurality of substrates 10 provided with the meandering wires 20 containing the thermoelectric material that has an anomalous Nernst effect allows the total extension of the wires containing the thermoelectric material to be increased in length. Thus, a sufficient electromotive voltage per unit installation area can be obtained also in the case of a small temperature difference.

Furthermore, the substrates 10 adjacent to each other are arranged at an angle that is larger than 0 degrees and smaller than 180 degrees, thereby allowing an electromotive voltage to be obtained from heat fluxes in a plurality of directions.

For example, in FIGS. 17 and 18, in a case where the meandering wires 20 are magnetized in the positive direction of the y axis, an electromotive voltage can be obtained from heat fluxes in three directions perpendicular to each substrate 10.

As illustrated in FIGS. 17 and 18, a pair of substrates facing each other in the y-axis direction may be disposed. In addition, although not shown in FIGS. 17 and 18, external electrodes electrically connected to the meandering wires 20 are preferably provided on the surface of the thermoelectric conversion device 3.

The material constituting the substrate 10 is not particularly limited, but is preferably a ceramic material that is low in thermal conductivity and low in electrical conductivity. Examples of the ceramic material constituting the substrate 10 include an aluminum nitride, a boron nitride, a silicon carbide, alumina, a spinel-type oxide, and a perovskite-type oxide. The material constituting the substrate 10 may be a ceramic material, a glass material, or a resin material. In a case where the thermoelectric material and the substrate 10 are subjected to co-firing, the material is preferably a low-temperature co-fired ceramic material for keeping the ordered phase of the thermoelectric material from being changed. Examples of the low-temperature co-fired ceramic material include a composite material containing borosilicate glass and alumina. From the viewpoint of causing a larger heat flow to flow through the meandering wire 20 to generate a higher electromotive voltage, the ceramic material constituting the substrate 10 is preferably lower in thermal conductivity. In the case of measuring an instantaneous change in heat flux, however, the ceramic material constituting the substrate 10 is preferably higher in thermal conductivity from the viewpoint of causing the heat flow to flow quickly to the thermoelectric conversion device 3. From the viewpoint of suppressing an electrical short circuit between the meandering wires 20, the ceramic material constituting the substrate 10 is preferably lower in electrical conductivity.

The material constituting the substrate 10 may contain a material that has a temperature coefficient of resistance. For example, when the substrate 10 contains an NTC material, the ambient temperature and the heat flux can be simultaneously measured by forming an internal conductor for temperature detection inside the chip component.

For the thermoelectric conversion device according to the third embodiment of the present invention, a magnet is preferably disposed on one end surface of the chip component from the viewpoint of increasing the electromotive voltage. In that case, on an end surface facing the end surface with the magnet disposed thereon, another magnet oriented to the same magnetic pole is more preferably disposed. For example, for the thermoelectric conversion device 3 illustrated in FIGS. 17 and 18, a magnet is preferably disposed on one of the end surfaces facing each other in the y-axis direction, and another magnet oriented to the same magnetic pole is more preferably disposed on the other end surface.

In a case where a magnet is disposed on the end surface of the chip component, the magnetic field direction formed by the magnet is preferably a direction perpendicular to the direction in which the current flows through the first wire and the heat flow direction. For example, in the thermoelectric conversion device 3 illustrated in FIGS. 17 and 18, a magnetic field is preferably formed in the y-axis direction.

For the thermoelectric conversion device according to the third embodiment of the present invention, a high thermal conductive member such as a heat dissipation sheet is preferably disposed on at least one end surface of the chip component from the viewpoint of increasing the temperature gradient, and thus increasing the electromotive voltage.

For the thermoelectric conversion device according to the third embodiment of the present invention, at least one end surface of the chip component preferably has irregularities from the viewpoint of enhancing the heat dissipation performance to increase the electromotive voltage.

The thermoelectric conversion device according to the third embodiment of the present invention may include a plurality of meandering wires that differ in orientation between the substrates.

### EXAMPLES

Hereinafter, examples that more specifically disclose the thermoelectric conversion device according to the present invention will be described. It is to be noted that the present invention is not to be considered limited only to these examples.

### Example 1

A thermoelectric material represented by the chemical formula Mn₃Sn, including an ordered structure DO3, was subjected to grinding to obtain a thermoelectric material powder of 5 μm in average particle size. The average particle size of the thermoelectric material powder is preferably 0.05 μm or more and 300 μm or less.

The thermoelectric material powder was mixed with a resin binder, an organic solvent, a dispersant, and a plasticizer to obtain a thermoelectric material paste.

A low-temperature co-fired ceramic powder obtained by mixing a borosilicate glass powder and an alumina powder was mixed with a resin binder, an organic solvent, a dispersant, and a plasticizer to obtain an element body paste.

A silver (Ag) powder was mixed with a resin binder, an organic solvent, a dispersant, and a plasticizer to obtain a conductive paste.

An element body layer of 20 μm in thickness was formed by screen printing with the element body paste.

On the upper surface of the element body layer, a meandering wire with the structure shown in FIG. 2 was formed by screen printing with the thermoelectric material paste and screen printing with the conductive paste.

The negative screen for the meandering wire was used for printing with the element body paste.

The printing mentioned above was repeated to obtain a green chip including a stacked structure. The ends of the meandering wires were exposed at both ends of the green chip.

The green chip was subjected to degreasing under a heating condition at 350° C. for 2 hours in the air. Then, the green chip was subjected to firing under a heating condition at 900° C. for 1 hour in an argon atmosphere.

The fired chip was subjected to barrel finishing, then, an external electrode paste was applied to the chip, and the chip with the paste was subjected to baking and plating, and washed and dried.

Thus, the thermoelectric conversion device 1 was obtained.

### Example 2

With the use of a thermoelectric material represented by the chemical formula Fe₃Al, including an ordered structure DO3, a winding wire of 250 μm in wire diameter was obtained by a melt spinning method. The wire diameter of the winding wire is preferably 100 μm or more and 500 μm or less.

The surface of the winding wire was coated with an insulating coating of polyimide.

An alumina (Al₂O₃) powder of 2 μm in average particle size was mixed with an organic solvent, a dispersant, and a plasticizer, and then spray-dried to obtain an element-body granulated powder.

The element-body granulated powder was press-molded, and then subjected to degreasing and firing to obtain a winding core.

The winding wire for 20 turns was wound around the winding core.

On the bottom surface of a flange of the winding core, electrodes were formed.

The ends of the winding wire were connected to the electrodes on the bottom surface of the flange of the winding core.

Thus, the thermoelectric conversion device 2 was obtained.

### Example 3

A thermoelectric material represented by the chemical formula Mn₃Sn, including an ordered structure DO3, was subjected to grinding to obtain a thermoelectric material powder of 5 μm in average particle size. The average particle size of the thermoelectric material powder is preferably 0.05 μm or more and 300 μm or less.

The thermoelectric material powder was mixed with a thermosetting resin binder, an organic solvent, a dispersant, and a plasticizer to obtain a thermoelectric material paste.

On the surfaces of alumina (Al₂O₃) substrates, meandering wires with the structure shown in FIG. 18 were formed by screen printing with thermoelectric material paste and screen printing with a conductive adhesive. The ends of the meandering wires were exposed at both ends of the substrate.

For the alumina substrates with the meandering wires formed, the conductive paste was subjected to curing under a heating condition at 250° C. for 2 hours in the air.

Three of the fired substrates were arranged mutually at an angle of 60 degrees, and bonded to each other.

Thus, the thermoelectric conversion device 3 was obtained.

### Calculation of Sensor Sensitivity

For the thermoelectric conversion device 1 illustrated in FIG. 2, the thermoelectric conversion device 1B illustrated in FIG. 5, and the thermoelectric conversion device 2 illustrated in FIG. 15, the sensitivity as a sensor was calculated by the following equation.

Sensitivity [V/(W*m⁻²)]=S_{N}·L/K

S_{N}: anomalous Nernst coefficient [V/K]

L: total length of magnetic wiring [m]

K: thermal conductivity of magnetic wiring [W/(m*K)]

Specifically, the sensitivity range (upper limit and lower limit) was calculated with the anomalous Nernst coefficient S_{N}: 1 to 6 μV/K and the thermal conductivity K: 15 to 25 W/(m*K).

For the thermoelectric conversion device 1 illustrated in FIG. 2, the sensitivity was calculated with the overall size: 2 mm×2 mm, the number of layers stacked: 1 layer or 20 layers, the width of the first wire 21/the width of the second wire 22/the interval between the meandering wires 20: 20 μm/20 μm/20 μm, and the side gap (the distance between the end surface of the substrate 10 and the meandering wire 20 in the x-axis direction): 30 μm.

The sensitivity obtained when the number of layers stacked is 1 is 0.002 to 0.019 μV/(W*m⁻²), whereas the sensitivity obtained when two or more layers are stacked is increased in response to the number of layers stacked. For example, the sensitivity obtained when the number of layers stacked is 20 is 0.038 to 0.376 μV/(W*m⁻²), which is much higher than that obtained when the number of layers stacked is 1.

For the thermoelectric conversion device 1B illustrated in FIG. 5, the sensitivity was calculated with the overall size: 2 mm×2 mm, the number of layers stacked: 1 layer or 10 layers, the width of the first wire 21/the width of the second wire 22/the interval between the meandering wires 20B: 20 μm/20 μm/20 μm, and the side gap (the distance between the substrate 10 and the meandering wire 20B in the x-axis direction): 30 μm.

The sensitivity obtained when the first wire 21 corresponding to the magnetic wiring has one layer is 0.004 to 0.038 μV/(W*m⁻²), whereas the sensitivity obtained when two or more layers are stacked is increased in response to the number of layers stacked. For example, the sensitivity obtained ten layers of the first wire 21 corresponding to the magnetic wiring are stacked is 0.038 to 0.376 μV/(W*m⁻²), which is much higher than that obtained when the number of layers stacked is 1.

For the thermoelectric conversion device 2 illustrated in FIG. 15, the sensitivity was calculated with the size of the bottom surface: 4 mm×4 mm, the diameter of the winding wire core: 2 mm, the height of the winding wire core: 3 mm, and the diameter of the winding wire: 200 μm (1 turn or 3 turns).

The sensitivity in the case of one turn is 0.004 to 0.039 μV/(W*m⁻²), whereas the sensitivity in the case of two or more turns is increased in response to the number of turns. For example, the sensitivity obtained in the case of three turns is 0.013 to 0.134 μV/(W*m⁻²), which is much higher as compared with the case of one turn.

### DESCRIPTION OF REFERENCE SYMBOLS

1, 1A, 1B, 1C, 1D, 1E, 1F, 1G, 1H, 2, 3: Thermoelectric conversion device
10: Substrate
11: Element body
20, 20A, 20B, 20C, 20D, 20E, 20F, 20G, 20H: Meandering wire
21: First wire
22: Second wire
23: Via conductor
24, 25: External electrode
30: Winding core
40: Winding wire
41, 42: Electrode
I: Current direction
M: Magnetization direction
Q: Heat flow direction

1. A thermoelectric conversion device comprising:
an element body including:
a plurality of stacked substrates; and
a meandering wire inside the element body and that has a stacked structure,
wherein the meandering wire includes a thermoelectric material that has an anomalous Nernst effect, and
a thermal conductivity of the plurality of stacked substrates is lower than that of the thermoelectric material.

2. The thermoelectric conversion device according to claim 1, wherein the meandering wire extends in a main surface direction of each of the plurality of stacked substrates and the stacked structure is arranged in a stacking direction of each of the plurality of stacked substrates.

3. The thermoelectric conversion device according to claim 1, wherein the meandering wire extends in a stacking direction of each of the plurality of stacked substrates and the stacked structure is arranged in a main surface direction of each of the plurality of stacked substrates.

4. The thermoelectric conversion device according to claim 1, wherein the meandering wire has a coil shape.

5. The thermoelectric conversion device according to claim 1, wherein the meandering wire is on a main surface of each of the plurality of stacked substrates.

6. The thermoelectric conversion device according to claim 1, wherein the meandering wire includes a first wire including the thermoelectric material and a second wire including a conductor.

7. The thermoelectric conversion device according to claim 6, wherein the first wire and the second wire are alternately arranged on a main surface of each of the plurality of stacked substrates.

8. The thermoelectric conversion device according to claim 6, wherein the first wire and the second wire are alternately arranged on a main surfaces of adjacent stacked substrates of the plurality of stacked substrates.

9. The thermoelectric conversion device according to claim 1, wherein the meandering wire includes only a first wire including the thermoelectric material.

10. The thermoelectric conversion device according to claim 1, wherein the meandering wire is on a main surface of each of the plurality of stacked substrates.

11. The thermoelectric conversion device according to claim 1, wherein the thermoelectric material is selected from Fe₃Sn, Fe₃Al, Fe₃Ga, Fe₃Ge, Co₂MnGa, Co₂MnAl, Co₂MnIn, Mn₃Ga, Mn₃Sn, Mn₃Ge, Fe₂NiGa, CoTiSb, CoVSb, CoCrSb, CoMnSb, and TiGa₂Mn.

12. A thermoelectric conversion device comprising:
a winding core; and
a winding wire wound around the winding core,
wherein the winding wire consist only of a thermoelectric material that has an anomalous Nernst effect.

13. The thermoelectric conversion device according to claim 12, wherein the thermoelectric material is selected from Fe₃Sn, Fe₃Al, Fe₃Ga, Fe₃Ge, Co₂MnGa, Co₂MnAl, Co₂MnIn, Mn₃Ga, Mn₃Sn, Mn₃Ge, Fe₂NiGa, CoTiSb, CoVSb, CoCrSb, CoMnSb, and TiGa₂Mn.

14. A thermoelectric conversion device comprising:
a plurality of substrates; and
a plurality of meandering wires on respective main surfaces of each of the plurality of substrates,
wherein
the plurality of meandering wires include a thermoelectric material that has an anomalous Nernst effect, and
adjacent substrates of the plurality of substrates are arranged at an angle that is larger than 0 degrees and smaller than 180 degrees.

15. The thermoelectric conversion device according to claim 14, wherein the thermoelectric material is selected from Fe₃Sn, Fe₃Al, Fe₃Ga, Fe₃Ge, Co₂MnGa, Co₂MnAl, Co₂MnIn, Mn₃Ga, Mn₃Sn, Mn₃Ge, Fe₂NiGa, CoTiSb, CoVSb, CoCrSb, CoMnSb, and TiGa₂Mn.

16. The thermoelectric conversion device according to claim 1, wherein the thermoelectric conversion device is a chip component.

17. The thermoelectric conversion device according to claim 16, further comprising first a magnet disposed on a first end surface of the chip component.

18. The thermoelectric conversion device according to claim 17, further comprising a second magnet disposed on a second end surface facing the first end surface, the second magnet being oriented to a same magnetic pole as the first magnet.

19. The thermoelectric conversion device according to claim 16, further comprising a thermal conductive member disposed on at least one end surface of the chip component.

20. The thermoelectric conversion device according to claim 16, wherein at least one end surface of the chip component has irregularities.
